(19) United States
(12) Patent Application Publication
(10) Pub. No.: US 2023/0245928 A1
(43) Pub. Date: Aug. 3, 2023

(54) TEMPERATURE-BASED SEMICONDUCTOR WAFER SINGULATION

(71) Applicant: TEXAS INSTRUMENTS INCORPORATED, Dallas, TX (US)

(72) Inventors: Jeniffer ASPURIA, Baguio City (PH); Jose Franco ALICANTE, Baguio City (PH); Jesus BAUTISTA, Jr., Baguio City (PH)

(21) Appl. No.: 17/590,697

(22) Filed: Feb. 1, 2022

(51) Int. Cl. H01L 21/784

(52) U.S. Cl. CPC H01L 21/784; H01L 23/3114

(57) ABSTRACT

In examples, a method for manufacturing a semiconductor package comprises forming a column of stealth damage locations along a thickness of a semiconductor wafer using a laser, each of the stealth damage locations having a semiconductor wafer crack associated therewith. The method also includes applying a first temperature to the semiconductor wafer to cause the semiconductor wafer to expand. The method includes applying a second temperature less than the first temperature to the semiconductor wafer to cause the semiconductor wafer to contract and to join two of the semiconductor wafer cracks with another semiconductor wafer crack. A difference between the first and second temperatures is at least 100 degrees Celsius.

### BACKGROUND

Semiconductor chips are often housed inside semiconductor packages that protect the chips from deleterious environmental influences, such as heat, moisture, and debris. A packaged chip communicates with electronic devices outside the package via conductive members, such as leads, that are exposed to surfaces of the package. Within the package, the chip may be electrically coupled to the conductive members using any suitable technique. One such technique is the flip-chip technique, in which the semiconductor chip (also called a “die”) is flipped so the device side of the chip (in which circuitry is formed) is facing downward. The device side is coupled to the conductive members using, e.g., solder bumps. Another technique is the wirebonding technique, in which the device side of the semiconductor chip is oriented upward and is coupled to the conductive members using bond wires.

### SUMMARY

In examples, a method for manufacturing a semiconductor package comprises forming a column of stealth damage locations along a thickness of a semiconductor wafer using a laser, each of the stealth damage locations having a semiconductor wafer crack associated therewith. The method also includes applying a first temperature to the semiconductor wafer to cause the semiconductor wafer to expand. The method includes applying a second temperature less than the first temperature to the semiconductor wafer to cause the semiconductor wafer to contract and to join two of the semiconductor wafer cracks with another semiconductor wafer crack. A difference between the first and second temperatures is at least 100 degrees Celsius.

### BRIEF DESCRIPTION OF THE DRAWINGS

For a detailed description of various examples, reference will now be made to the accompanying drawings in which:

FIG. 1A is a perspective view of a semiconductor wafer, in accordance with various examples.

FIG. 1B is a top-down view of a semiconductor wafer, in accordance with various examples.

FIG. 2A is a cross-sectional view of a semiconductor wafer undergoing a laser cutting process, in accordance with various examples.

FIG. 2B is a top-down view of a semiconductor wafer undergoing a laser cutting process, in accordance with various examples.

FIG. 3A is a cross-sectional view of a semiconductor wafer being heated according to a temperature-based wafer singulation process, in accordance with various examples.

FIG. 3B is a top-down view of a semiconductor wafer being heated according to a temperature-based wafer singulation process, in accordance with various examples.

FIG. 4 is a cross-sectional view of a semiconductor wafer being cooled according to a temperature-based wafer singulation process, in accordance with various examples.

FIG. 5A is a cross-sectional view of a semiconductor wafer being stretched to form individual semiconductor dies, in accordance with various examples.

FIG. 5B is a top-down view of a semiconductor wafer being stretched to form individual semiconductor dies, in accordance with various examples.

FIG. 6A is a cross-sectional view of a semiconductor package covering a semiconductor die formed according to a temperature-based wafer singulation process, in accordance with various examples.

FIG. 6B is a top-down view of a semiconductor package including a semiconductor die formed according to a temperature-based wafer singulation process, in accordance with various examples.

FIG. 7 is a flow diagram of a method for performing a temperature-based wafer singulation process, in accordance with various examples.

### DETAILED DESCRIPTION

During the manufacturing process for a semiconductor package, multiple circuits are repetitively formed on a device side of a semiconductor wafer, and the wafer is subsequently cut to produce multiple semiconductor dies, each die containing one or more of the circuits. Each semiconductor die has a device side and a non-device side that is opposite the device side. The device side includes circuitry, and the non-device side does not include circuitry. The semiconductor die is coupled to a die pad and is electrically coupled to conductive terminals. A mold compound is then applied to cover the semiconductor die, with the conductive terminals being exposed to an exterior surface of the mold compound.

A die may be cut from a wafer using a variety of techniques, including mechanical saws and laser cuts. A laser may cut a wafer into individual dies by forming a vertical column of stealth damage locations along a thickness of the wafer. A stealth damage location is a laser-induced area of damage in the wafer. Each stealth damage location is formed using a different laser focal point. For example, a stealth damage location deeper in the wafer may be formed using a focal point relatively far from the laser, while a stealth damage location closer to the wafer's top surface may be formed using a focal point relatively close to the laser. The stealth damage locations are formed in a staggered manner, separated from each other by a predetermined distance. The formation of a stealth damage location also results in the formation of cracks spreading outward from the stealth damage location. The lengths of the cracks may depend at least in part on the energy or power level of the laser that is used to form the stealth damage locations, with greater laser energy resulting in longer cracks and lesser laser energy resulting in shorter cracks. In some cases, a sufficiently strong laser may be used such that the cracks connect to each other. In other cases, a weaker laser is used so the cracks do not connect to each other but instead are separated by relatively thin cleavage points. In the latter cases, the wafer is then stretched such that the cleavage points break, thus resulting in the formation of a set of individual semiconductor dies. A sidewall of a resulting die may display physical signs of the laser cutting process, such as so-called black lines where the cleavage points were previously located as well as stealth damage locations and cracks emanating from the stealth damage locations.

Such traditional laser cutting techniques present a number of problems. When a high energy laser is used to cut a wafer, the above-described cracks may form in unintended patterns. When the laser is again applied during the formation of a subsequent stealth damage location, the aberrant cracks may catch and reflect and/or diffract the laser light, causing stealth damage locations or other types of damage in unintended areas of the wafer. Such unintentional damage points may be called laser splash points. Laser splash reduces manufacturing yield and increases expense. High energy lasers may also cause chipping of wafers or a meandering cut line that is not consistently aligned with a wafer scribe street. Such chipping and meandering also reduce yield and increase costs. Although laser splash, chipping, and meandering are caused by high laser energy levels, lowering the laser energy levels frequently results in incomplete cuts, and, therefore, incomplete separation of the individual dies of the wafer. Unless dies are fully separated, they cannot be used in semiconductor packages, and thus yield is again reduced and costs are again increased.

This disclosure describes the use of lasers and the application of wide temperature differentials to cut semiconductor wafers in a manner that mitigates the problems described above. More specifically, a low intensity (low energy) laser is applied to a semiconductor wafer to produce a vertical column of stealth damage locations. These stealth damage locations are associated with cracks that propagate outward from the stealth damage locations. The cracks formed by the laser do not connect to each other, meaning that the cracks are not in fluid communication with each other. Stated yet another way, cleavage points remain between the cracks after the laser has been applied to the wafer. After the laser process is complete, the wafer is heated and then rapidly cooled such that the wafer is subjected to a temperature differential of approximately 100 degrees Celsius to 150 degrees Celsius within the span of 120 or fewer seconds. The abrupt and significant change in temperature causes the semiconductor material (e.g., silicon) to expand and then rapidly contract, thereby creating stress within the silicon and causing the cracks to propagate farther such that at least some of the cracks connect to each other (e.g., join in fluid communication with each other). In some examples, the cracks completely separate the individual dies from each other, and in other examples, cleavage points remain between at least some of the cracks. The wafer is then stretched, thereby separating the individual dies from each other. A die is then picked and placed onto a die pad and electrically coupled to one or more conductive terminals. A mold compound is applied to cover the die. The one or more conductive terminals are exposed to an exterior surface of the mold compound. By using a low intensity laser, the splashing, chipping, and meandering problems described above are avoided. Further, by heating and then rapidly and significantly cooling the wafer, the pre-existing cracks propagate to an extent that the incomplete separation problem associated with low intensity laser cuts (as described above) is mitigated. Thus, manufacturing yield increases and costs decrease.

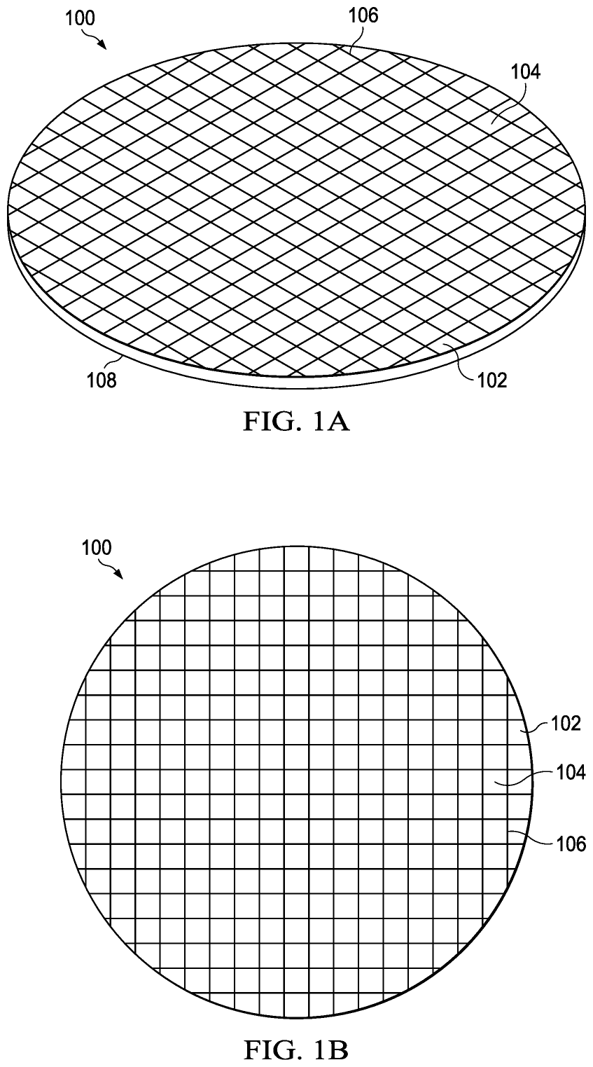

FIGS. 1A-6B depict a process flow for a temperature-based semiconductor wafer singulation. FIG. 7 is a flow diagram of a method 700 for the temperature-based semiconductor wafer singulation. Accordingly, the process flow of FIGS. 1A-6B is now described in parallel with the method 700 of FIG. 7.

FIG. 1A is a perspective view of a semiconductor wafer 100, in accordance with various examples. The wafer 100 may be composed of any suitable semiconductor material, such as silicon, gallium nitride, etc. The wafer 100 includes a device side 102 on which circuitry is formed. For example, multiple circuits may be formed on the device side of the wafer 100, with each circuit 104 or set of circuits 104 separated from another by one or more scribe streets 106. The wafer 100 also includes a non-device side 108. FIG. 1B is a top-down view of the semiconductor wafer 100, in accordance with various examples.

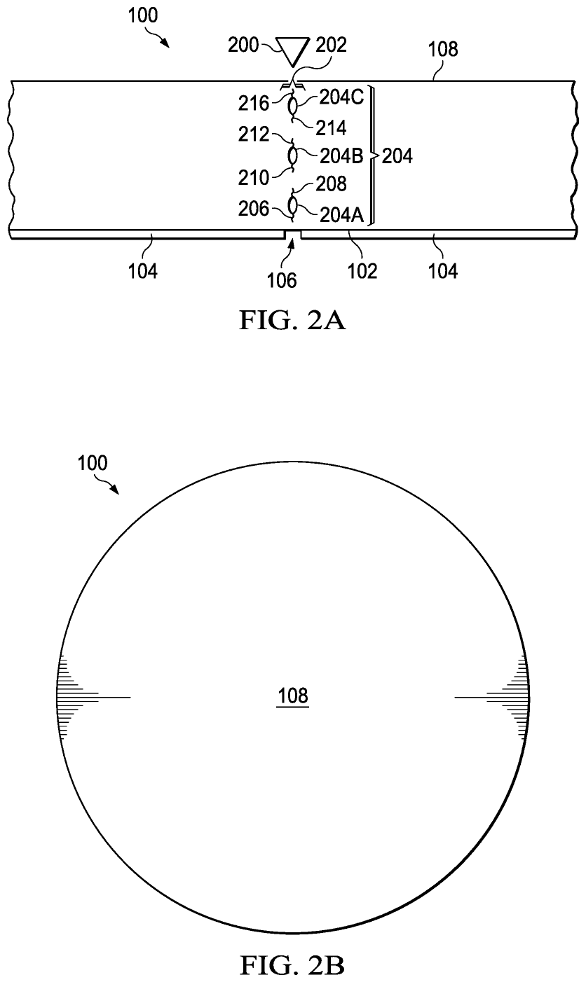

The method 700 begins with forming a column of laser-induced stealth damage locations in a semiconductor wafer, where the stealth damage locations are associated with cracks in the wafer (702). FIG. 2A is a cross-sectional view of a semiconductor wafer undergoing a laser cutting process, in accordance with various examples. More specifically, a laser 200 (represented as a triangle) is applied via the non-device side 108 along a thickness of the wafer 100 to form a column 202 of stealth damage locations 204. A stealth damage location is a laser-induced area of damage in the wafer 100. In examples, the stealth damage locations 204 are vertically aligned.

In examples, to create each stealth damage location 204, the focal point of the laser 200 is trained on a different area of the wafer 100. For example, to form the stealth damage location 204A, the laser 200 is trained on an area of the wafer 100 that is closer to the device side 102 than the area of the wafer 100 on which the laser 200 is trained to form the stealth damage location 204B, and so on. Each of the stealth damage locations 204 is associated with (i.e., is in fluid communication with) one or more cracks. For example, the stealth damage location 204A is associated with cracks 206 and 208; the stealth damage location 204B is associated with cracks 210 and 212; and the stealth damage location 204C is associated with cracks 214 and 216.

The intensity (i.e., power or energy) of the laser 200 may determine, at least in part, the sizes of the stealth damage locations 204. Further, the intensity of the laser 200 may determine, at least in part, the lengths of the cracks associated with the stealth damage locations 204. For example, a relatively high intensity laser 200 may result in a larger stealth damage location 204A and/or longer cracks 206 and 208. Conversely, a relatively low intensity laser 200 may result in a smaller stealth damage location 204A and/or shorter cracks 206 and 208. A sufficiently high intensity of laser 200 may result in cracks that are so long that they connect (i.e., are in fluid communication with) with cracks of adjacent stealth damage locations. For example, if a sufficiently high intensity laser 200 is used, the cracks 208 and 210 may be joined in fluid communication with each other. Conversely, if a lower intensity laser 200 is used, the cracks 208 and 210 would not be joined in fluid communication with each other. In examples, an intensity of the laser 200 is used that does not result in fluid communication between adjacent cracks. To achieve crack formation without fluid communication between the cracks, the intensity of the laser 200 ranges between 0.2 Watts and 0.4 Watts, with an intensity of the laser 200 lower than this range resulting in excessive distance between cracks that will prevent subsequent joining of the cracks with the application of heat and cooling as described below, and with an intensity of the laser 200 higher than this range resulting in undesired fluid communication between the cracks, as well as the various disadvantages described above in relation to the use of high-powered lasers. The distance between adjacent cracks (e.g., between cracks 208 and 210, or between cracks 210 and 212) ranges from 25 microns to 80 microns, with a lower distance resulting in undesired fluid communication between the cracks, and with a greater distance preventing subsequent joining of the cracks with the application of heating and cooling as described below. FIG. 2B is a top-down view of a semiconductor wafer undergoing a laser cutting process, in accordance with various examples.

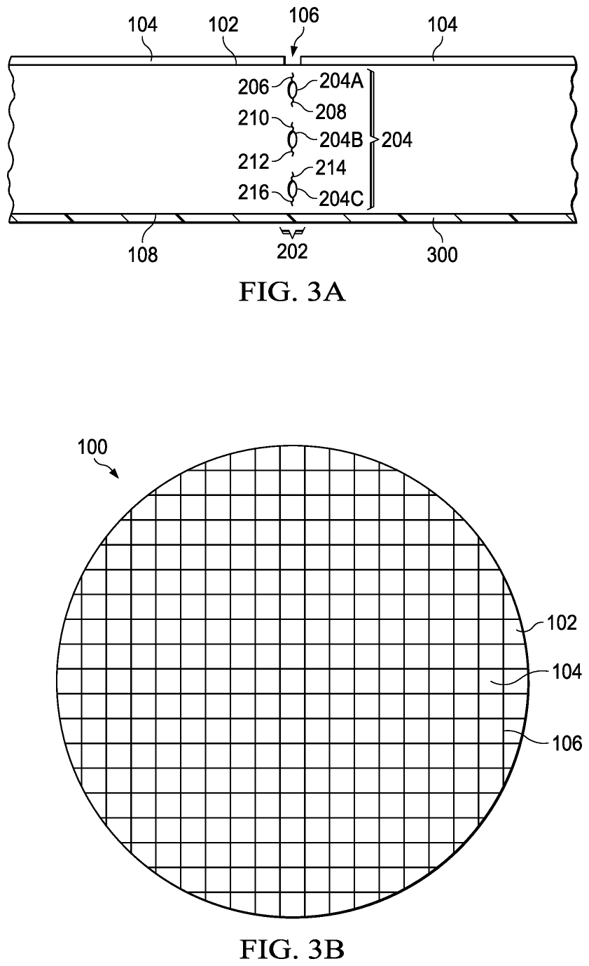

The method 700 continues with heating the semiconductor wafer to a first temperature (704). FIG. 3A is a cross-sectional view of the semiconductor wafer 100 being heated according to a temperature-based wafer singulation process, in accordance with various examples. In examples, a dicing tape 300 is applied to the non-device side 108, and the structure of FIG. 3A is subsequently heated, for example, by placing the structure on a heating table or in a heating chamber. The structure of FIG. 3A is heated to a temperature between 100 degrees Celsius and 150 degrees Celsius, with a temperature higher than this range being disadvantageous because it will damage the tape coupled to the wafer, and with a temperature lower than this range being disadvantageous because it will not achieve the abrupt temperature change needed to create the cracks. The time duration for which the target heating temperature is applied ranges from 5 minutes to 10 minutes, with an exposure to the target heating temperature longer than this range being disadvantageous because it causes damage to the dicing tape 300 that is coupled to the wafer 100, and with an exposure to the target heating temperature shorter than this range being disadvantageous because it will not achieve a desired target temperature. FIG. 3B is a top-down view of a semiconductor wafer being heated according to a temperature-based wafer singulation process, in accordance with various examples.

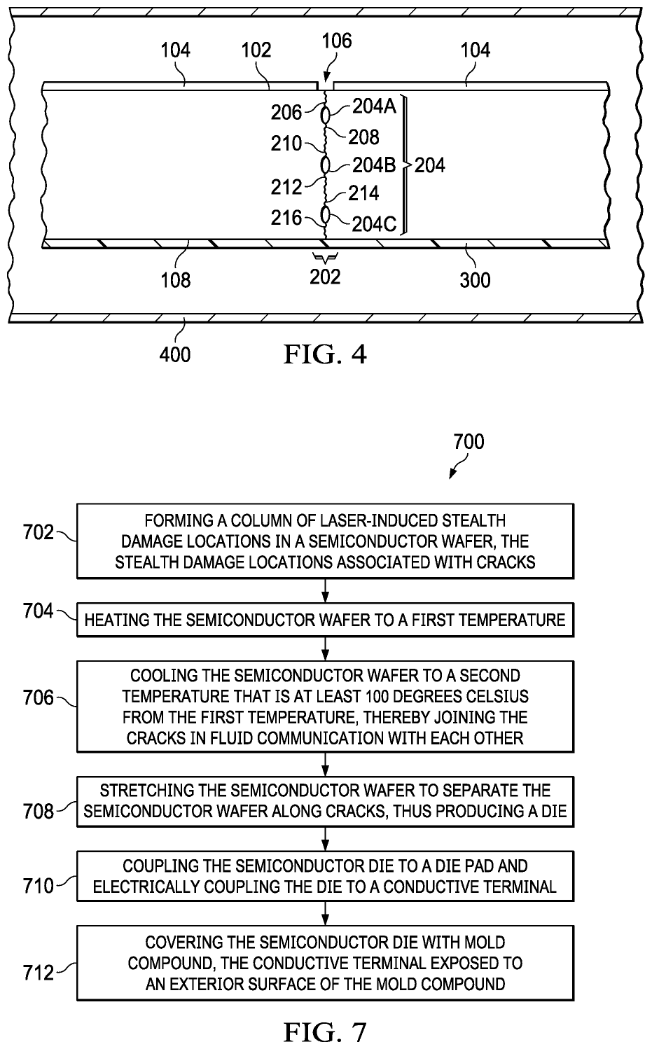

The method 700 includes cooling the semiconductor wafer to a second temperature that is cooler than the first temperature, thereby joining the cracks in fluid communication with each other (706). FIG. 4 is a cross-sectional view of the semiconductor wafer 100 being cooled in a cooling chamber 400 according to a temperature-based wafer singulation process, in accordance with various examples. The wafer 100 may be cooled by applying a target cooling temperature to the wafer 100 after the wafer 100 has been heated to the target heating temperature. The target cooling temperature is sufficiently lower than the target heating temperature, and the time between application of the target heating temperature and the target cooling temperature is sufficiently short, such that the wafer 100 expands and rapidly contracts to extend the cracks associated with the stealth damage locations 204, thereby causing the adjacent cracks (e.g., cracks 208, 210) to join in fluid communication with each other. The target cooling temperature is no higher than −5 degrees Celsius, with a temperature above this range being disadvantageous because it will not achieve the abrupt temperature change needed to form the cracks. The time between the end of the application of the target heating temperature and the start of the application of the target cooling temperatures is less than 2 minutes, with a longer time being disadvantageous because it will not achieve the abrupt temperature change needed to form the cracks. The time duration for which the target cooling temperature is applied ranges from 1 minute to 5 minutes, with a longer duration being disadvantageous because it will freeze the dicing tape 300 coupled to the wafer 100 and cause the dicing tape 300 to become brittle. As adjacent cracks extend in length and join in fluid communication with each other, the wafer 100 is singulated into multiple individual semiconductor dies.

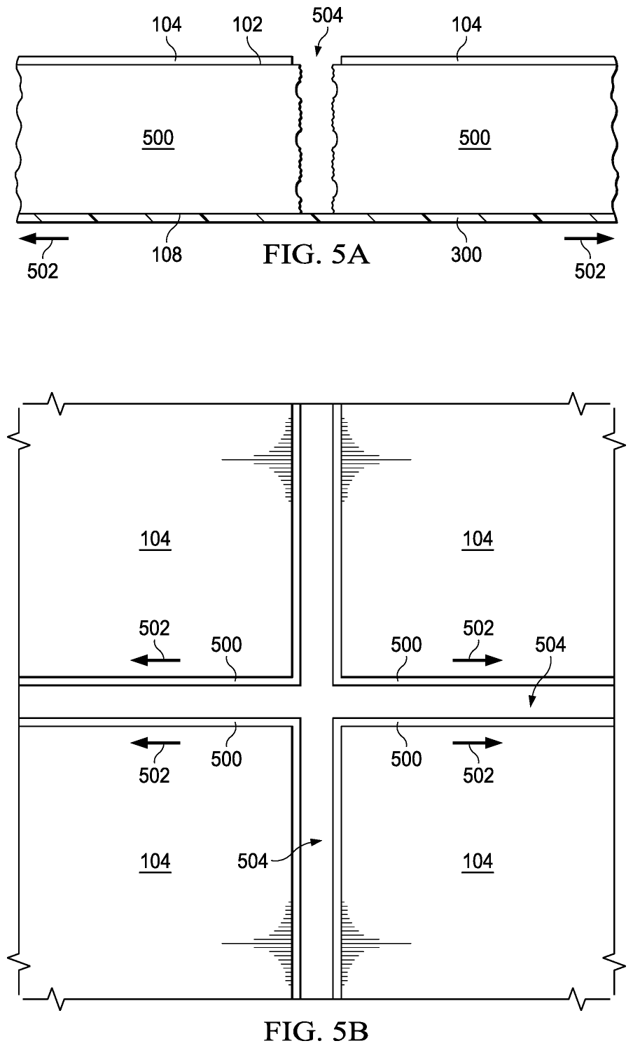

The method 700 includes stretching the semiconductor wafer to separate the semiconductor wafer along the cracks, thereby producing a semiconductor die (708). FIG. 5A is a cross-sectional view of the semiconductor wafer 100 being stretched to form individual semiconductor dies, in accordance with various examples. More specifically, the dicing tape 300 is coupled to a flex frame (not expressly shown) and is expanded or stretched so the wafer 100 is stretched in a direction circumferentially outward from a center of the wafer 100. The application of this force causes the individual dies 500 of the wafer 100 to separate from each other. The arrows 502 indicate the force applied, and the gaps 504 indicate the spaces that form between the individual dies 500 of the wafer 100 as the wafer 100 is stretched. FIG. 5B is a top-down view of the semiconductor wafer 100 being stretched to form individual semiconductor dies 500, in accordance with various examples.

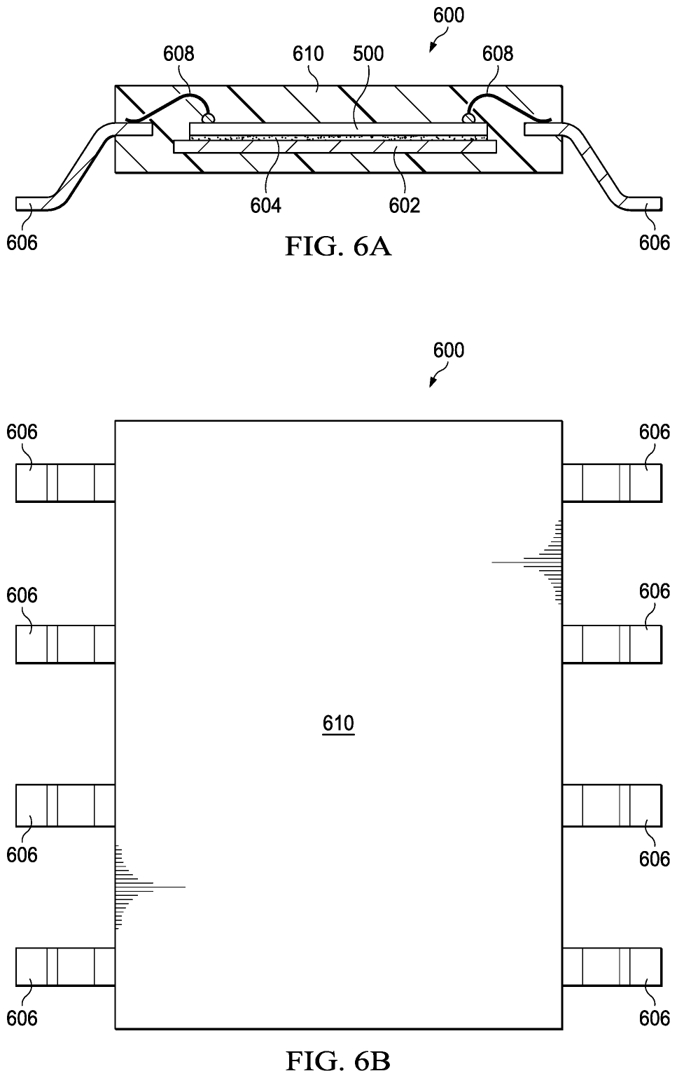

The method 700 includes coupling the semiconductor die to a die pad and electrically coupling the die to a conductive terminal (710). The method 700 also includes covering the semiconductor die with a mold compound, the conductive terminal exposed to an exterior surface of the mold compound (712). FIG. 6A is a cross-sectional view of a semiconductor package 600 including a semiconductor die 500 formed according to the temperature-based wafer singulation process described herein, in accordance with various examples. The package 600 includes the die 500 coupled to a die pad 602 by way of a die attach film 604. The package 600 also includes conductive terminals 606 (e.g., leads in a gullwing-style dual inline package) that are coupled to the device side of the die 500 by way of bond wires 608. A mold compound 610 covers the various structures of the package 600. Other types of packages are also contemplated, including ball grid array (BGA) packages, packages in which the device side of the die is oriented downward or upward, quad flat no lead (QFN) packages, etc. FIG. 6B is a top-down view of the semiconductor package 600, in accordance with various examples.

Unless otherwise stated, “about,” “approximately,” or “substantially” preceding a value means +/−10 percent of the stated value. Modifications are possible in the described examples, and other examples are possible within the scope of the claims.

What is claimed is:

1. A method for manufacturing a semiconductor package, comprising:
forming a column of stealth damage locations along a thickness of a semiconductor wafer using a laser, each of the stealth damage locations having a semiconductor wafer crack associated therewith;
applying a first temperature to the semiconductor wafer to cause the semiconductor wafer to expand; and
applying a second temperature less than the first temperature to the semiconductor wafer to cause the semiconductor wafer to contract and to join two of the semiconductor wafer cracks with another semiconductor wafer crack,
wherein a difference between the first and second temperatures is at least 100 degrees Celsius.

2. The method of claim 1, further comprising stretching the semiconductor wafer to separate the semiconductor wafer along the two semiconductor wafer cracks.

3. The method of claim 1, wherein a time between the application of the first temperature and the application of the second temperature is less than 2 minutes.

4. The method of claim 1, further comprising applying the first temperature for a duration ranging from 5 minutes to 10 minutes.

5. The method of claim 1, further comprising applying the second temperature for a duration of less than 2 minutes.

6. The method of claim 1, wherein forming the column of stealth damage locations includes using a power of the laser ranging from 0.2 Watts to 0.4 Watts.

7. The method of claim 1, wherein a distance between the stealth damage locations in the column ranges from 25 microns to 80 microns.

8. A method for manufacturing a semiconductor package, comprising:
forming a first stealth damage location in a semiconductor wafer using a laser, the first stealth damage location in fluid communication with a first semiconductor wafer crack;
forming a second stealth damage location in the semiconductor wafer, the second stealth damage location in fluid communication with a second semiconductor wafer crack; and
heating the semiconductor wafer and subsequently cooling the semiconductor wafer so as to form a third semiconductor crack that joins the first and second semiconductor cracks in fluid communication with each other.

9. The method of claim 8, wherein heating the semiconductor wafer includes applying a first temperature to the semiconductor wafer and cooling the semiconductor wafer includes applying a second temperature to the semiconductor wafer, a difference between the first and second temperatures being at least 100 degrees Celsius.

10. The method of claim 9, wherein a time between application of the first and second temperatures does not exceed 2 minutes.

11. The method of claim 10, wherein heating the semiconductor wafer includes applying the first temperature to the semiconductor wafer for a time ranging from 5 minutes to 10 minutes, and wherein cooling the semiconductor wafer includes applying the second temperature to the semiconductor wafer for another time ranging from 1 minute to 5 minutes.

12. The method of claim 8, wherein forming the first and second stealth damage locations includes using a laser power ranging from 0.2 Watts to 0.4 Watts.

13. The method of claim 8, wherein a distance between the first and second stealth damage locations ranges from 25 microns to 80 microns.

14. The method of claim 8, wherein the first and second stealth damage locations are in a vertical column.

15. A method for manufacturing a semiconductor package, comprising:
providing a semiconductor wafer having a first stealth damage location and a first semiconductor wafer crack in fluid communication with the first stealth damage location, the semiconductor wafer having a second stealth damage location and a second semiconductor wafer crack in fluid communication with the second stealth damage location;
heating the semiconductor wafer to a first temperature;
cooling the semiconductor wafer to a second temperature that is at least 100 degrees from the first temperature, thereby joining the first and second semiconductor wafer cracks in fluid communication with each other;
stretching the semiconductor wafer to separate the semiconductor wafer along the first and second semiconductor wafer cracks, thereby producing a semiconductor die;
coupling the semiconductor die to a die pad and electrically coupling the semiconductor die to a conductive terminal; and
covering the semiconductor die with a mold compound, the conductive terminal exposed to an exterior surface of the mold compound.

16. The method of claim 15, wherein a time between application of the first and second temperatures does not exceed 2 minutes.

17. The method of claim 15, wherein heating the semiconductor wafer includes applying the first temperature to the semiconductor wafer for a time ranging from 5 minutes to 10 minutes, and wherein cooling the semiconductor wafer includes applying the second temperature to the semiconductor wafer for another time ranging from 1 minute to 5 minutes.

18. The method of claim 15, wherein forming the first and second stealth damage locations includes using a laser power ranging from 0.2 Watts to 0.4 Watts.

19. The method of claim 15, wherein a distance between the first and second stealth damage locations ranges from 25 microns to 80 microns.

20. The method of claim 15, wherein the first and second stealth damage locations are vertically aligned.
